(19) United States
(12) Patent Application Publication
(10) Pub. No.: US 2014/0024172 A1
(43) Pub. Date: Jan. 23, 2014

(54) VAPOR DEPOSITION APPARATUS FOR CONTINUOUS DEPOSITION AND TREATMENT OF A THIN FILM LAYER ON A SUBSTRATE

(71) Applicants: Christopher Rathweg, Boulder, CO (US); Scott Daniel Feldman-Peabody, Golden, CO (US)

(72) Inventors: Christopher Rathweg, Boulder, CO (US); Scott Daniel Feldman-Peabody, Golden, CO (US)

(73) Assignee: PRIMESTAR SOLAR, INC., Arvada, CO (US)

(21) Appl. No.: 13/554,423

(22) Filed: Jul. 20, 2012

(51) Int. Cl. H01L 21/363

(52) U.S. Cl. 438/102; 118/726; 257/E21.462

(57) ABSTRACT

Apparatus and method for vapor deposition of a sublimated source material are generally provided. The apparatus includes a deposition head with a first sublimation compartment and a second sublimation compartment, each configured for receipt and sublimation of a source material. A first distribution plate can be positioned at a first defined distance above a horizontal conveyance plane of an upper surface of substrates conveyed through a first deposition area of the apparatus, and a second distribution plate can be positioned at a second defined distance above a horizontal conveyance plane of an upper surface of substrates conveyed through a second deposition area of said apparatus. The first sublimation compartment and the second sublimation compartment can be isolated from each other such that the sublimated first source material is substantially prevented from mixing with the sublimated second source material, at least during sublimation.

### FIELD OF THE INVENTION

The subject matter disclosed herein relates generally to methods and systems for depositing thin films during manufacture of cadmium telluride photovoltaic devices. More particularly, the subject matter disclosed herein relates generally to integrated systems for the deposition of a cadmium telluride layer and subsequent cadmium chloride treatment during manufacture of cadmium telluride photovoltaic devices, and their methods of use.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. For example, CdTe has an energy bandgap of about 1.45 eV, which enables it to convert more energy from the solar spectrum as compared to lower bandgap semiconductor materials historically used in solar cell applications (e.g., about 1.1 eV for silicon). Also, CdTe converts radiation energy in lower or diffuse light conditions as compared to the lower bandgap materials and, thus, has a longer effective conversion time over the course of a day or in cloudy conditions as compared to other conventional materials.

The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type layer (i.e., a positive, electron accepting layer) and the CdS layer acts as a n-type layer (i.e., a negative, electron donating layer). Free carrier pairs are created by light energy and then separated by the p-n heterojunction to produce an electrical current.

During the production of CdTe PV modules, the surface of the CdTe PV module is typically cooled, transported to a subsequent treatment apparatus for cadmium chloride treatment (e.g., a cadmium chloride wash), and then subsequently annealed. This process of heating, cooling, and re-heating is inefficient in both energy consumption and cost. Additionally, the cadmium telluride layer is exposed to the environment during transport to the subsequent treatment apparatus. Such exposure can result in the introduction of additional atmospheric materials into the cadmium telluride layer, which can lead to the introduction of impurities in the CdTe PV module. Additionally, the room atmosphere naturally varies over time, adding a variable to a large-scale manufacturing process of the CdTe PV modules. Such impurities and additional variables can lead to inconsistent CdTe PV modules from the same manufacturing line and process.

Thus, a need exists for methods and systems for reducing the introduction of impurities and additional variables into a large-scale manufacturing process of making the CdTe PV modules, as well as increasing the energy efficiency of the process.

### BRIEF DESCRIPTION OF THE INVENTION

Aspects and advantages of the invention will be set forth in part in the following description, or may be obvious from the description, or may be learned through practice of the invention.

Apparatus is generally provided for vapor deposition of a sublimated source material as a thin film on discrete photovoltaic module substrates conveyed in a continuous non-stop manner therethrough. In one embodiment, the apparatus can include a deposition head with a first sublimation compartment and a second sublimation compartment. The first sublimation compartment can be configured for receipt and sublimation of a first source material, and the second sublimation compartment can be configured for receipt and sublimation of a second source material. A first distribution plate can be positioned at a first defined distance above a horizontal conveyance plane of an upper surface of substrates conveyed through a first deposition area of the apparatus. The first distribution plate is generally positioned between the first sublimation compartment and the horizontal conveyance plane so as to define the first deposition area. A second distribution plate can be positioned at a second defined distance above a horizontal conveyance plane of an upper surface of substrates conveyed through a second deposition area of said apparatus. The first distribution plate is generally positioned between the first sublimation compartment and the horizontal conveyance plane so as to define the second deposition area.

In one embodiment, the first defined distance and the second defined distance can be substantially identical.

The first sublimation compartment and the second sublimation compartment can be isolated from each other such that the sublimated first source material is substantially prevented from mixing with the sublimated second source material, at least during sublimation (e.g., prior to passing through the respective distribution plate and/or within the first deposition area and the second deposition area). For example, in one embodiment, a seal member can be positioned between the first distribution plate and a second distribution plate such that source vapors are substantially prevented from mixing between the first deposition area and the second deposition area. Althernatively, the first deposition area and the second deposition area can define a single continuous deposition area.

Methods are also generally provided for depositing a thin film on a substrate. For example, a first source material can be heated in a first receptacle positioned within a first chamber of a deposition head to form first source vapors, which can then be directed through a first distribution plate. A second source material can be heated in a second receptacle positioned within a second chamber of the deposition head to form second source vapors, which can be directed through the distribution plate. substrate can be transported past the distribution plate such that a first majority of the first source vapors deposit on a deposition surface of the substrate prior to a second majority of the second source vapors.

These and other features, aspects, and advantages of the present invention will become better understood with reference to the following description and appended claims, or may be obvious from the description or claims, or may be learned through practice of the invention.

### BRIEF DESCRIPTION OF THE DRAWINGS

A full and enabling disclosure of the present invention, including the best mode thereof, is set forth in the specification, which makes reference to the appended drawings, in which:

FIG. 1 is a plan view of a system that may incorporate embodiments of a vapor deposition apparatus of the present invention;

FIG. 2 is a cross-sectional view of an embodiment of a vapor deposition apparatus according to aspects of the invention in a first operational position;

FIG. 3 is a cross-sectional view of the embodiment of FIG. 2 in a second operational position;

FIG. 4 is a cross-sectional view of the embodiment of FIG. 2 in cooperation with a substrate conveyor; and,

FIG. 5 is a top view of the receptacle component within the embodiment of FIG. 2.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment, can be used with another embodiment to yield a still further embodiment. Thus, it is intended that the present invention encompass such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers. Thus, these terms are simply describing the relative position of the layers to each other and do not necessarily mean “on top of” since the relative position above or below depends upon the orientation of the device to the viewer.

Additionally, although the invention is not limited to any particular film thickness, the term “thin” describing any film layers of the photovoltaic device generally refers to the film layer having a thickness less than about 10 micrometers (“microns” or “μm”).

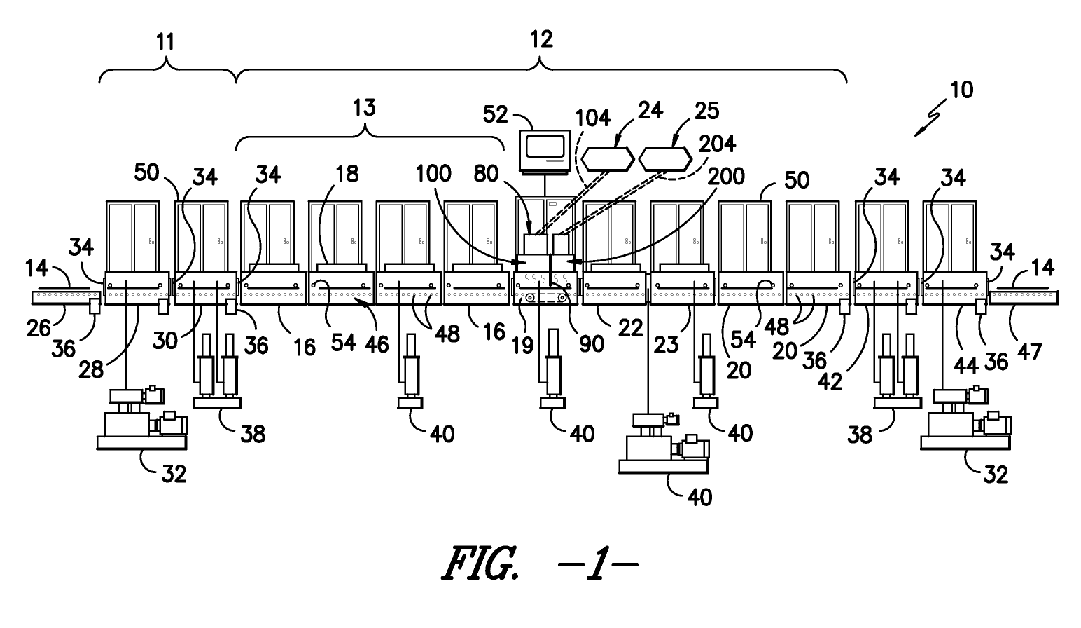

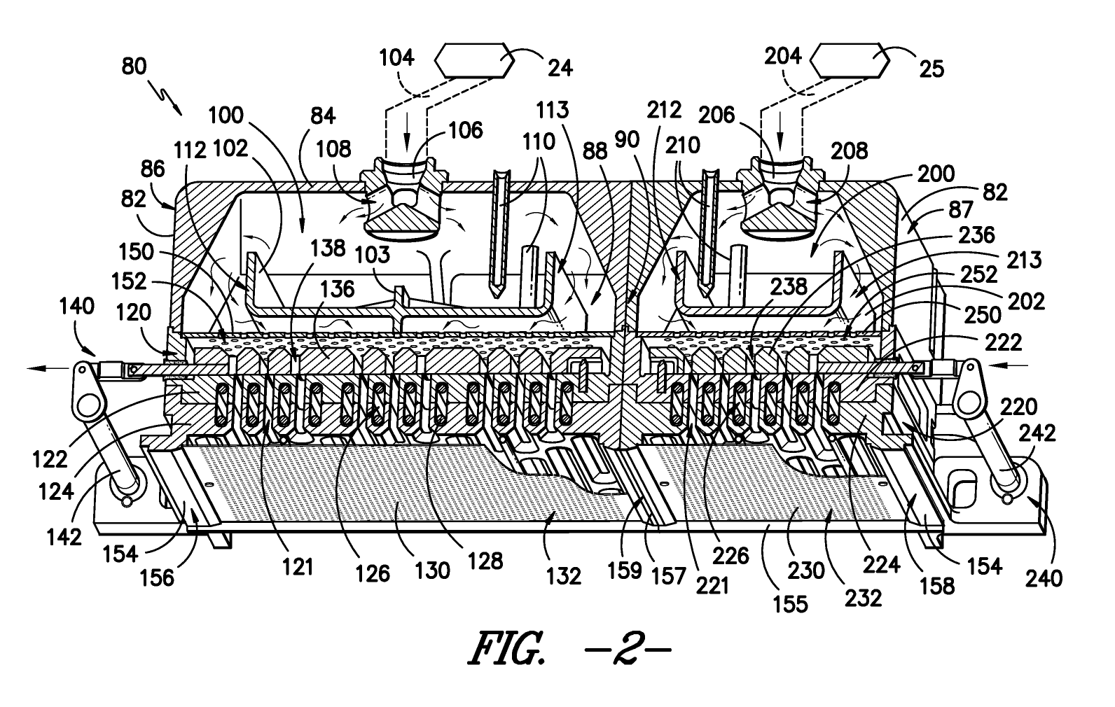

FIG. 1 illustrates an embodiment of a system 10 that may incorporate a vapor deposition apparatus 19 (FIGS. 2 through 5) within the system in accordance with embodiments of the invention configured for deposition of a thin film layer on a photovoltaic (PV) module substrate 14 (referred to hereafter as a “substrate”) and subsequent treatment. The thin film may be, for example, a film layer of cadmium telluride (CdTe), and the subsequent treatment may be, for instance, cadmium chloride treatment to the cadmium telluride film layer. It should be appreciated that the present system 10 is not limited to the vapor deposition chamber 19 illustrated in FIGS. 2-5.

Referring to FIG. 1, the individual substrates 14 are initially placed onto a load conveyor 26, and are subsequently moved into an entry vacuum lock station 11 that includes a load vacuum chamber 28 and a load buffer chamber 30. A “rough” (i.e., initial) vacuum pump 32 is configured with the load vacuum chamber 28 to drawn an initial load pressure, and a “fine” (i.e., final) vacuum pump 38 is configured with the load buffer chamber 30 to increase the vacuum (i.e. decrease the initial load pressure) in the load buffer chamber 30 to reduce the vacuum pressure within the entry vacuum lock station 11. Valves 34 (e.g., gate-type slit valves or rotary-type flapper valves) are operably disposed between the load conveyor 26 and the load module 28, between the load vacuum chamber 28 and the load buffer chamber 30, and between the load vacuum chamber 30 and the heating station 13. These valves 34 are sequentially actuated by a motor or other type of actuating mechanism 36 in order to introduce the substrates 14 into the vacuum lock station 11 in a step-wise manner without affecting the vacuum within the subsequent heating station 13.

In operation of the system 10, an operational vacuum is maintained in the vacuum chamber 12 by way of any combination of rough and/or fine vacuum pumps 40. In order to introduce a substrate 14 into the load vacuum station 11, the load vacuum chamber 28 and load buffer chamber 30 are initially vented (with the valve 34 between the two modules in the open position). The valve 34 between the load buffer chamber 30 and the first heater module 16 is closed. The valve 34 between the load vacuum chamber 28 and load conveyor 26 is opened, and a substrate 14 is moved into the load vacuum chamber 28. At this point, the first valve 34 is shut, and the rough vacuum pump 32 then draws an initial vacuum in the load vacuum chamber 28 and load buffer chamber 30. The substrate 14 is then conveyed into the load buffer chamber 30, and the valve 34 between the load vacuum chamber 28 and load buffer chamber 30 is closed. The fine vacuum pump 38 then increases the vacuum in the load buffer chamber 30 to approximately the same vacuum in the vacuum chamber 12 and the heating station 13. At this point, the valve 34 between the load buffer chamber 30 and heating station 13 is opened, and the substrate 14 is conveyed into the first heater module 16.

Thus, the substrates 14 are transported into the exemplary system 10 first through the load vacuum chamber 28 that draws a vacuum in the load vacuum chamber 28 to an initial load pressure. For example, the initial load pressure can be less than about 250 mTorr, such as about 1 mTorr to about 100 mTorr. Optionally, a load buffer chamber can reduce the pressure to about 1×10⁻⁷ Torr to about 1×10⁻⁴ Ton, and then backfilled with an inert gas (e.g., argon) in a subsequent chamber within the system 10 to a deposition pressure (e.g., about 10 mTorr to about 100 mTorr).

The substrates 14 can then be transported into and through a heating station 13 including heating chambers 16. The plurality of heating chambers 16 define a pre-heat section 13 of the system 10 through which the substrates 14 are conveyed and heated to a first deposition temperature before being conveyed into the vapor deposition chamber 19. Each of the heating chambers 16 may include a plurality of independently controlled heaters 18, with the heaters defining a plurality of different heat zones. A particular heat zone may include more than one heater 18. The heating chambers 16 can heat the substrates 14 to a deposition temperature, such as about 350° C. to about 600° C. Although shown with four heating chambers 16, any suitable number of heating chambers 16 can be utilized in the system 10.

The substrates 14 can then be transferred into and through the vapor deposition chamber 19 for deposition of a thin film onto the substrates 14 and subsequent treatment thereof. For example, the film can be a cadmium telluride thin film, and the treatment can be performed using cadmium chloride. The vapor deposition chamber 19 can include the deposition apparatus 80, such as shown in FIGS. 2-5 and discussed in greater detail below. As diagrammatically illustrated in FIG. 1, a first feed device 24 is configured with the vapor deposition apparatus 80 to supply a first source material, such as granular cadmium telluride. Additionally, a second feed device 25 is configured with the vapor deposition apparatus 80 to supply a second source material, such as granular cadmium chloride. The feed devices 24, may take on various configurations within the scope and spirit of the invention, and may function to supply the source material without interrupting the continuous vapor deposition process within the apparatus 80 or conveyance of the substrates 14 through the apparatus 80.

After deposition and treatment in the vapor deposition chamber 19, the substrates 14 can be transported into and through a post-heat chamber 22, an optional annealing chamber 23, and a series of cooling chambers 20. In the illustrated embodiment of system 10, at least one post-heat chamber 22 is located immediately downstream of the vapor deposition apparatus 19. The post-heat chamber 22 maintains a controlled heating profile of the substrate 14 until the entire substrate is moved out of the vapor deposition chamber 19, in order to prevent damage to the substrate 14, such as warping or breaking caused by uncontrolled or drastic thermal stresses. If, for example, the leading section of the substrate 14 were allowed to cool at an excessive rate as it exited the apparatus 19, a potentially damaging temperature gradient would be generated longitudinally along the substrate 14. This condition could result in breaking, cracking, or warping of the substrate from thermal stress.

In certain embodiments, the anneal chamber 23 (or a series of annealing chambers) can be present to further heat the substrates 14 sufficient to anneal the deposited material thereon. For example, the substrates 14 can be annealed in the anneal chamber 23 by heating, in certain embodiments, to an anneal temperature of about 500° C. to about 800° C. after treatment of the deposited cadmium telluride layer formed using the first sublimation compartment 100 by deposition with the cadmium chloride vapors in the second sublimation compartment 200.

A cool-down chamber(s) 20 is positioned downstream of the vapor deposition chamber. The cool-down chamber 20 allows the substrates 14 having the treated thin film to be conveyed and cooled at a controlled cool-down rate prior to the substrates 14 being removed from the system 10. The cool down chamber 20 may include a forced cooling system wherein a cooling medium, such as chilled water, refrigerant, gas, or other medium, is pumped through cooling coils (not illustrated) configured with the chamber 20. In other embodiments, a plurality of cool down chambers 20 can be utilized in the system 10.

An exit vacuum lock station 15 is configured downstream of the cool-down chamber 20, and operates essentially in reverse of the entry vacuum lock station 11 described above. For example, the exit vacuum lock station 15 may include an exit buffer module 42 and a downstream exit lock module 44. Sequentially operated valves 34 are disposed between the buffer module 42 and the last one of the cool-down modules 20, between the buffer module 42 and the exit lock module 44, and between the exit lock module 44 and an exit conveyor 47. A fine vacuum pump 38 is configured with the exit buffer module 42, and a rough vacuum pump 32 is configured with the exit lock module 44. The pumps 32, 38 and valves 34 are sequentially operated to move the substrates 14 out of the system 10 in a step-wise fashion without loss of vacuum condition within the system 10.

System 10 also includes a conveyor system 46 configured to move the substrates 14 into, through, and out of each of load vacuum station 12, the pre-heating station 13, the vapor deposition chamber 19, the post-heat chamber 22, and the cooling chambers 20. In the illustrated embodiment, this conveyor system 46 includes a plurality of individually controlled conveyors 48, with each of the various modules including a respective one of the conveyors 48. It should be appreciated that the type or configuration of the conveyors 48 may vary. In the illustrated embodiment, the conveyors 48 are roller conveyors having rotatably driven rollers that are controlled so as to achieve a desired conveyance rate of the substrates 14 through the respective module and the system 10 overall.

As described, each of the various modules and respective conveyors in the system 10 are independently controlled to perform a particular function. For such control, each of the individual modules may have an associated independent controller 50 configured therewith to control the individual functions of the respective module. The plurality of controllers 50 may, in turn, be in communication with a central system controller 52, as diagrammatically illustrated in FIG. 1. The central system controller 52 can monitor and control (via the independent controllers 50) the functions of any one of the modules so as to achieve an overall desired heat-up rate, deposition rate, cool-down rate, conveyance rate, and so forth, in processing of the substrates 14 through the system 10.

Referring to FIG. 1, for independent control of the individual respective conveyors 48, each of the modules may include any manner of active or passive sensors 54 that detects the presence of the substrates 14 as they are conveyed through the module. The sensors 54 are in communication with the respective module controller 50, which is in turn in communication with the central controller 52. In this manner, the individual respective conveyor 48 may be controlled to ensure that a proper spacing between the substrates 14 is maintained and that the substrates 14 are conveyed at the desired conveyance rate through the vacuum chamber 12.

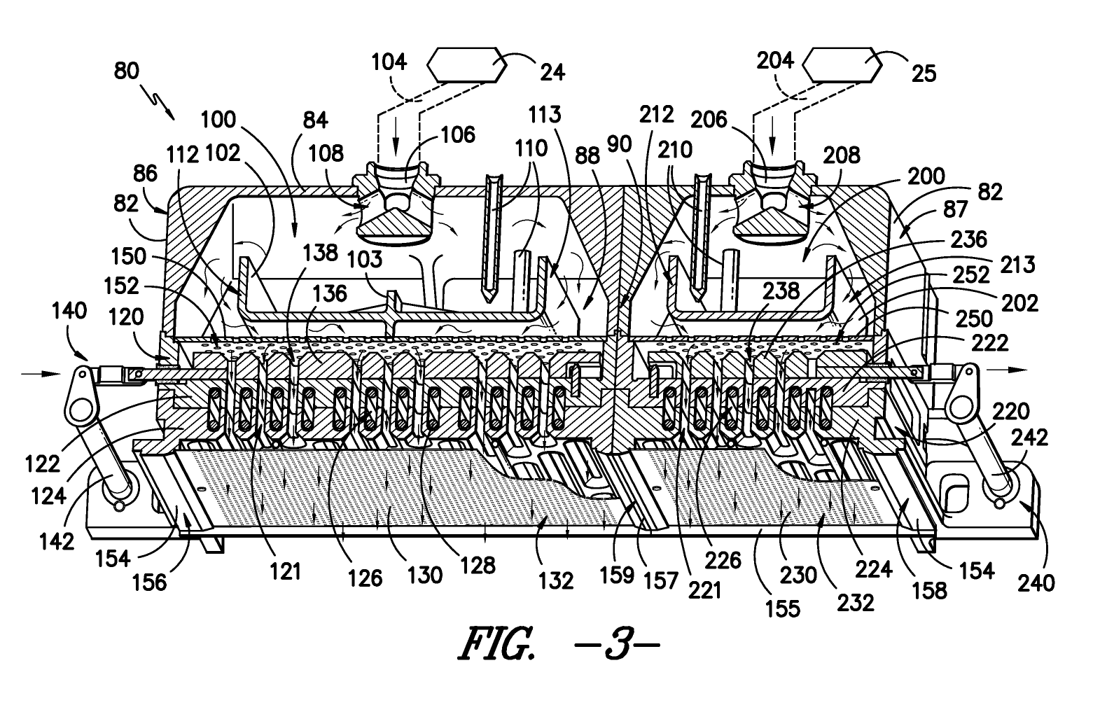

FIGS. 2 through 5 relate to a particular embodiment of the vapor deposition apparatus 80, which can be utilized in conjunction with the vapor deposition chamber 19. Referring to FIGS. 2 and 3 in particular, the apparatus 80 includes a deposition head 82 that is divided into two compartments: a first sublimation compartment 100 and a second sublimation compartment 200. During deposition, the substrates 14 pass first under the first sublimation compartment 100 for deposition of a first material (e.g., cadmium telluride) and then under the second sublimation compartment 200 for deposition of a second material (e.g., a treatment material, such as cadmium chloride, copper chloride, etc.). As stated above, following deposition in the vapor deposition chamber 80, the substrates 14 pass into the post-heat chamber 22. Additionally, the substrates 14 can pass through an optional anneal chamber 23, if desired, to anneal the deposited thin film layer and treatment material.

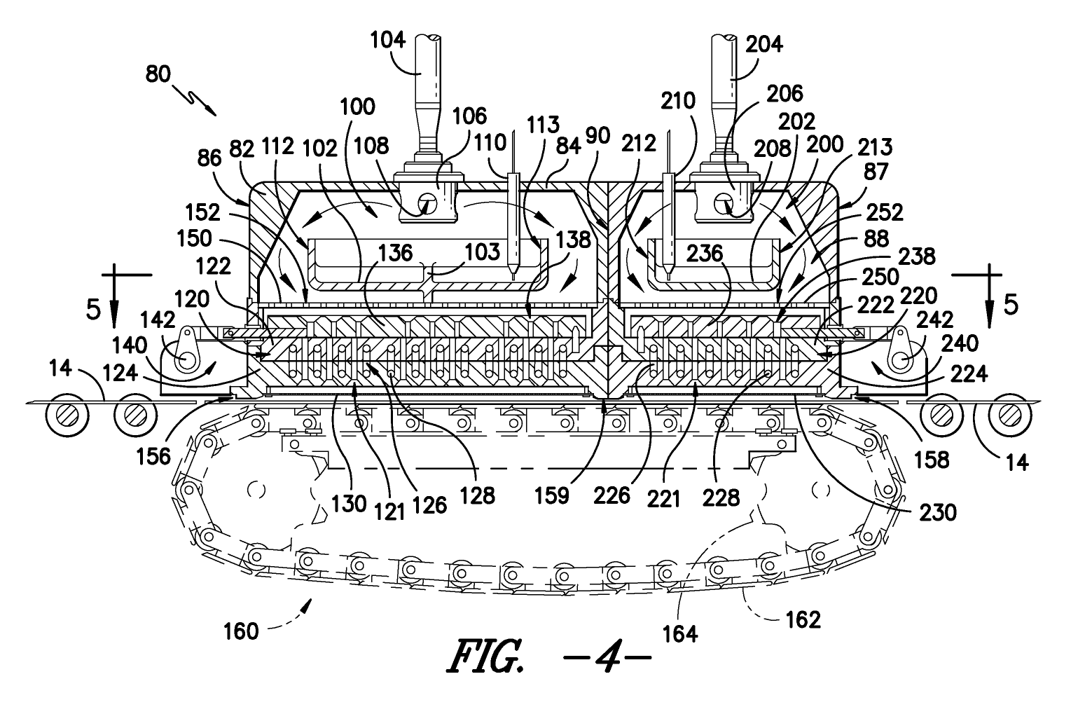

Referring to the first sublimation compartment 100, receptacle 102 is configured for receipt of a source material (not shown). As mentioned, the source material may be supplied by a first feed device 24 via a feed tube 104 (FIG. 4). The first feed tube 104 is connected to a first distributor 106 disposed in a first opening in a top wall 84 of the deposition head 82. The first distributor 106 includes a plurality of discharge ports 108 that are configured to evenly distribute the granular source material into the first receptacle 102. The first receptacle 102 has an open top and may include any configuration of internal rib elements 103 or other structural elements. In the illustrated embodiment, a first thermocouple 110 is operationally disposed through the top wall 84 of the deposition head 82 to monitor temperature within the first sublimation compartment 100 adjacent to or in the first receptacle 102. Additionally thermocouples 110 can be included within the first sublimation compartment 100, if desired, to monitor the temperature in various areas.

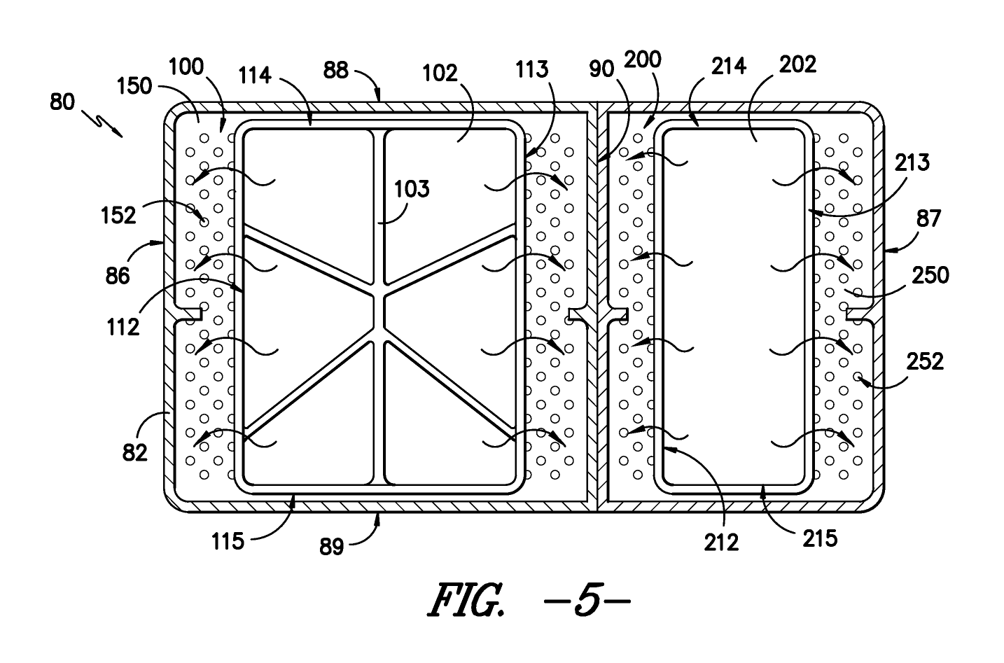

The deposition head 82 also includes oppositely positioned lateral end walls 86, 87 and oppositely positioned longitudinal side walls 88, 89 (FIG. 5). An internal lateral wall 90 is positioned between the first sublimation compartment 100 and the second sublimation compartment 200. As such, the source material in the first sublimation compartment 100 and in the second sublimation compartment 200 are isolated from each other while in the deposition head 82.

Referring to FIG. 5 in particular, the receptacle 102 within the first sublimation compartment 100 has a shape and configuration such that the transversely extending end walls 112, 113 of the receptacle 102 are spaced from the lateral end wall 86 and the internal lateral wall 90, respectively. The side walls 114, 115 are lie adjacent to and in close proximity to the longitudinal side walls 88, 89, respectively, of the first sublimation compartment 100 so that very little clearance exists between the respective walls, as depicted in FIG. 5. With this configuration, sublimated source material will flow out of the open top of the receptacle 102 and downwardly over the end walls 112, 113 as leading and trailing curtains of vapor (shown as flow lines with arrows depicting an exemplary direction of flow), as depicted by the flow lines in FIGS. 2, 3, and 5. Very little of the sublimated source material will thus be able to flow over the side walls 114, 115 of the receptacle 102.

A first heated distribution manifold 120 is disposed below the first receptacle 102. This distribution manifold 120 may take on various configurations within the scope and spirit of the invention, and serves to indirectly heat the first receptacle 102, as well as to distribute the sublimated source material that flows from the first receptacle 102. In the illustrated embodiment, the heated distribution manifold 120 has a clam-shell configuration that includes an upper shell member 122 and a lower shell member 124. Each of the shell members 122, 124 includes recesses therein that define cavities 126 when the shell members are mated together, as depicted in FIGS. 2 and 3. Heater elements 128 are disposed within the cavities 126 and serve to heat the distribution manifold 120 to a degree sufficient for indirectly heating the source material within the first receptacle 102 to cause sublimation of the source material. The heater elements 128 may be made of a material that reacts with the source material vapor and, in this regard, the shell members 122, 124 also serve to isolate the heater elements 128 from contact with the source material vapor. The heat generated by the distribution manifold 120 is also sufficient to prevent the sublimated source material from plating out onto components of the head chamber 82. Desirably, the coolest component in the head chamber 82 is the upper surface of the substrates 14 conveyed through the apparatus 80 so as to ensure that the sublimated source material plates onto the substrate 14, and not onto components of the deposition head 82.

Still referring to FIGS. 2 and 3, the first heated distribution manifold 120 includes a plurality of passages 121 defined therethrough. These passages 121 have a shape and configuration so as to help uniformly distribute the sublimated source material from the first sublimation compartment 100 towards the underlying substrates 14 (FIG. 4).

Similar to the discussion above, with respect to the first sublimation compartment 100, the second sublimation compartment 200 includes a second receptacle 202 configured for receipt of a second source material (not shown). As mentioned, the second source material may be supplied by a second feed device 25 via a second feed tube 204 (FIG. 4). The second feed tube 204 is connected to a second distributor 206 disposed in a second opening in a top wall 84 of the deposition head 82. The second distributor 206 includes a plurality of discharge ports 208 that are configured to evenly distribute the source material into the second receptacle 202. The second receptacle 102 has an open top and may include any configuration of internal rib elements (not shown) or other structural elements. In the illustrated embodiment, a second thermocouple 210 is operationally disposed through the top wall 84 of the deposition head 82 to monitor temperature within the second sublimation compartment 200 adjacent to or in the second receptacle 202. Additionally thermocouples 210 can be included within the second sublimation compartment 200, if desired, to monitor the temperature in various areas.

The second receptacle 202 within the second sublimation compartment 200 has a shape and configuration such that the transversely extending end walls 212, 213 of the receptacle 202 are spaced from the internal lateral wall 90 and the lateral end wall 87, respectively. The side walls 214, 215 are lie adjacent to and in close proximity to the longitudinal side walls 88, 89, respectively, of the second sublimation compartment 200 so that very little clearance exists between the respective walls, as depicted in FIG. 5. With this configuration, sublimated source material will flow out of the open top of the second receptacle 202 and downwardly over the end walls 212, 213 as leading and trailing curtains of vapor (shown as flow lines with arrows depicting an exemplary direction of flow), as depicted by the flow lines in FIGS. 2, 3, and 5. Very little of the sublimated source material will flow over the side walls 214, 215 of the receptacle 202.

A second heated distribution manifold 220 is disposed below the second receptacle 202. Similarly to the first distribution manifold 120, this second distribution manifold 220 may take on various configurations within the scope and spirit of the invention, and serves to indirectly heat the second receptacle 202, as well as to distribute the sublimated source material that flows from the second receptacle 202. In the illustrated embodiment, the heated distribution manifold 220 has a clam-shell configuration that includes an upper shell member 222 and a lower shell member 224. Each of the shell members 222, 224 includes recesses therein that define cavities 226 when the shell members are mated together as depicted in FIGS. 2 and 3. Heater elements 228 are disposed within the cavities 226 and serve to heat the distribution manifold 220 to a degree sufficient for indirectly heating the source material within the second receptacle 202 to cause sublimation of the source material. The heater elements 228 may be made of a material that reacts with the source material vapor and, in this regard, the shell members 222, 224 also serve to isolate the heater elements 228 from contact with the source material vapor. The heat generated by the distribution manifold 220 is also sufficient to prevent the sublimated source material from plating out onto components of the head chamber 82. Still referring to FIGS. 2 and 3, the second heated distribution manifold 220 includes a plurality of passages 221 defined therethrough. These passages have a shape and configuration so as to uniformly distribute the sublimated source material from the second sublimation compartment 200 towards the underlying substrates 14 (FIG. 4).

Since the first heated distribution manifold 120 can be separate from the second heated distribution manifold 220, as shown in the embodiment of FIGS. 2-4, the internal temperatures of the first sublimation compartment 100 and the second sublimation compartment 200 (e.g., the first receptacle 102 and the second receptacle 202) can be independently controlled. This independent control allows for material to be sublimated within the first sublimation compartment 100 and the second sublimation compartment 200 that has a different sublimation temperature and/or optimum sublimation conditions. Thus, two different materials can be deposited onto the substrates 14 as each passes through the vapor deposition chamber 19.

In the illustrated embodiment, first and second distribution plates 130, 230 are disposed below the first and second sublimation compartments, respectively. These distribution plates 130, 230 are positioned at a defined distance above a horizontal plane of the upper surface of an underlying substrate 14, as depicted in FIG. 4. This distance may be, for example, between about 0.3 cm to about 4.0 cm. In a particular embodiment, the distance is about 1.0 cm. The conveyance rate of the substrates below the distribution plates 130, 230 may be in the range of, for example, about 10 mm/sec to about 40 mm/sec. In a particular embodiment, this rate may be, for example, about 20 mm/sec. For example, when depositing cadmium telluride using the first sublimation compartment, the thickness of the CdTe film layer that plates onto the upper surface of the substrate 14 can vary within the scope and spirit of the invention, and may be, for example, between about 1 micron to about 5 microns. In a particular embodiment, the film thickness may be about 3 microns.

The first and second distribution plates 130, 230 include a pattern of passages 132, 232, respectively, such as holes, slits, and the like, therethrough that further distribute the sublimated source material passing through the distribution manifolds 120, 220 such that the source material vapors are substantially uninterrupted. In other words, the pattern of passages 132, 232 are shaped and staggered or otherwise positioned to ensure that the sublimated source material is deposited completely over the substrate in the transverse direction so that longitudinal streaks or stripes of “un-coated” regions on the substrate are avoided. As previously mentioned, a significant portion of the sublimated source material will flow out of the receptacles 102, 202 as leading and trailing curtains of vapor in both the first and second sublimation compartments 100, 200, as depicted in FIG. 5. Although these curtains of vapor will diffuse to some extent in the longitudinal direction prior to passing through the distribution plates 130, 230, it should be appreciated that it is unlikely that a uniform distribution of the sublimated source material will be achieved. In other words, more of the sublimated source material will be distributed through the longitudinal end sections of the distribution plates 130, 230 as compared to the middle portion of the distribution plates 130, 230. However, as discussed above, because the system 10 conveys the substrates 14 through the vapor deposition apparatus 80 at a constant (non-stop) linear speed, the upper surfaces of the substrates 14 will be exposed to the same deposition environment regardless of any non-uniformity of the vapor distribution along the longitudinal aspect of the apparatus 80. The passages 121, 221 in the distribution manifolds 120, 220 and the holes 132, 232 in the distribution plate 130, 230 ensure a relatively uniform distribution of the sublimated source material in the transverse aspect of the vapor deposition apparatus 80. So long as the uniform transverse aspect of the vapor is maintained, a relatively uniform thin film layer is deposited onto the upper surface of the substrates 14 regardless of any non-uniformity in the vapor deposition along the longitudinal aspect of the apparatus 80, due to the substantially constant rate at which the substrates 14 are moved in the longitudinal direction of the apparatus 80.

As illustrated in the figures, it may be desired to include debris shields 150, 250 between the receptacles 102, 202 and the distribution manifolds 120, 220, respectively. These debris shields 150, 250 includes holes 152, 252 defined therethrough (which may be larger or smaller than the size of the holes 132, 232 of the distribution plates 130, 230) and primarily serves to retain any granular or particulate source material from passing through and potentially interfering with operation of the movable components of the distribution manifolds 120, 220, as discussed in greater detail below. In other words, the debris shields 150, 250 can be configured to act as a breathable screen that inhibits the passage of particles without substantially interfering with vapors flowing therethrough.

Referring to FIGS. 2 through 4 in particular, apparatus 80 desirably includes transversely extending seals 154 at each longitudinal end of the head chamber 82. In the illustrated embodiment, the seals define an entry slot 156 and an exit slot 158 at the longitudinal ends of the head chamber 82. These seals 154 are disposed at a distance above the upper surface of the substrates 14 that is less than the distance between the surface of the substrates 14 and the distribution plate 130, 230, as is depicted in FIG. 4. The seals 154 help to maintain the sublimated source material in the deposition area above the substrates. In other words, the seals 154 prevent the sublimated source material from “leaking out” through the longitudinal ends of the apparatus 80. It should be appreciated that the seals 154 may be defined by any suitable structure. In the illustrated embodiment, the seals 154 are actually defined by components of the lower shell members 124, 224 of the heated distribution manifold 120, 220. It should also be appreciated that the seals 154 may cooperate with other structure of the vapor deposition apparatus 80 to provide the sealing function. For example, the seals may engage against structure of the underlying conveyor assembly in the deposition area.

In addition, an optional middle seal 157 can be positioned between the first distribution plate 130 and the second distribution plate 230 to define a separation slot 159. Like end seals 154, the optional middle seal 157 can be disposed at a distance above the horizontal conveyance plane defined by the upper surface of the substrates 14 that is less than the distance between the horizontal conveyance plane defined by the substrates 14 and the distribution plate 130, 230, as is depicted in FIG. 4. When present, the middle seal 157 can help to maintain the sublimated source material below the first and second sublimation compartments 100, 200 in the respective deposition area above the substrates. In other words, the middle seal 157 prevent the sublimated source material from mixing between the first deposition area defined under the first distribution plate 130 and the second deposition area defined under the second distribution plate 230. It should be appreciated that the middle seal 157 may be defined by any suitable structure. In the illustrated embodiment, the seal 157 is actually defined by components of the lower shell members 124, 224 of the heated distribution manifold 120, 220. It should also be appreciated that the seal 157 may cooperate with other structure of the vapor deposition apparatus 80 to provide the separation function. For example, the seals may engage against structure of the underlying conveyor assembly in the deposition area.

In an alternative embodiment, the sublimated material may be allowed to intermix in the deposition area above the substrates 14. In other words, the sublimated vapor material is, in such an embodiment, allowed to intermix within a single, continuous deposition area defined under the first distribution plate 130 and the second distribution plate 230. However, such intermixing may be somewhat controlled by varying the distance between the distribution plates 130, 230 and the horizontal conveyance plane defined by the upper surface of the substrates 14. For instance, if the distance between the distribution plates 130, 230 and the horizontal conveyance plane defined by the upper surface of the substrates 14 is relatively small, then little intermixing will be realized in practice due to the tendency of the sublimated source vapors to deposit on the substrates 14 relatively quickly. As such, increasing the distance between the distribution plates 130, 230 and the horizontal conveyance plane defined by the upper surface of the substrates 14 can result in more intermixing.

As such, in one embodiment, the distribution plates 130, 230 can define a single distribution plate defining holes therethrough, and positioned such that the first source vapors from the first sublimation compartment 100 and the second source vapors from the second sublimation compartment 200 pass through the distribution plate 130, 230. As the substrates 14 are conveyed past the deposition head 80, a first majority of the first source vapors can deposit on the deposition surface of the substrate 14 prior to a second majority of the second source vapors.

Any manner of longitudinally extending seal structures 155 may also be configured with the apparatus 80 to provide a seal along the longitudinal sides thereof. Referring to FIGS. 2 and 3, this seal structure 155 may include a longitudinally extending side member that is disposed generally as close as reasonably possible to the upper surface of the underlying convey surface so as to inhibit outward flow of the sublimated source material without frictionally engaging against the conveyor.

Referring to FIGS. 2 and 3, the illustrated embodiment includes movable shutter plates 136, 236 disposed above the distribution manifolds 120, 220. These shutter plates 136, 236 includes a plurality of passages 138, 238 defined therethrough that align with the passages 121 in the distribution manifold 120 in a first operational position of the shutter plates 136, 236 as depicted in FIG. 3. As can be readily appreciated from FIG. 3, in this operational position of the shutter plates 136, 236, the sublimated source material is free to flow through the passages 138, 238 defined in the shutter plates 136, 236, respectively, and through the passages 121, 221 in the distribution manifolds 120, 220 for subsequent distribution through the plates 130, 230. Referring to FIG. 2, the shutter plates 136, 236 are movable to a second operational position relative to the upper surfaces of the distribution manifolds 120, 220 wherein the passages 138, 238 in the shutter plates 136, 236 are misaligned with the passages 121, 221 in the distribution manifolds 120, 220, respectively. In this configuration, the sublimated source material is blocked from passing through the distribution manifolds 120, 220, and is essentially contained within the first and second sublimation compartments, respectively, of the head chamber 82. Any suitable actuation mechanism, generally 140 and 240 may be configured for moving the shutter plates 136, 236 between the first and second operational positions. In the illustrated embodiment, the actuation mechanisms 140, 240 include rods 142, 242 and any manner of suitable linkage that connects the rod 142, 242 to the respective shutter plate 136, 236. The rods 142, 242 can be moveable by any manner of mechanism located externally of the head chamber 82.

In the embodiment shown, the shutter plates 136, 236 can be independently moved between the first and second operational positions. That is, the flow of sublimation material from either of the first sublimation compartment 100 and the second sublimation compartment 200 can be controlled, regardless of the operational position of the other compartment.

The shutter plate 136, 236 configuration illustrated in FIGS. 2 and 3 is particularly beneficial in that, for whatever reason, the sublimated source material can be quickly and easily contained within the respective sublimation compartment 100, 200 of the head chamber 82 and prevented from passing through to the deposition area above the conveying unit. This may be desired, for example, during start up of the system 10 while the concentration of vapors within the head chamber builds to a sufficient degree to start the deposition process. Likewise, during shutdown of the system, it may be desired to maintain the sublimated source material within the head chamber 82 to prevent the material from condensing on the conveyor or other components of the apparatus 80.

Referring to FIG. 4, the vapor deposition apparatus 80 may further comprise a conveyor 160 disposed below the head chamber 82. This conveyor 160 may be uniquely configured for the deposition process as compared to the conveyors 48 discussed above with respect to the system 10 of FIG. 1. For example, the conveyor 160 may be a self-contained conveying unit that includes a continuous loop conveyor on which the substrates 14 are supported below the distribution plates 130, 230. In the illustrated embodiment, the conveyor 160 is defined by a plurality of slats 162 that provide a flat, unbroken (i.e., no gaps between the slats) support surface for the substrates 14. The slat conveyor is driven in an endless loop around sprockets 164. It should be appreciated, however, that the invention is not limited to any particular type of conveyor 160 for moving the substrates 14 through the vapor deposition apparatus 80.

The present invention also encompasses various process embodiments for vapor deposition of a sublimated source material to form a thin film on a PV module substrate, and subsequent vapor treatment. The various processes may be practiced with the system embodiments described above or by any other configuration of suitable system components. It should thus be appreciated that the process embodiments according to the invention are not limited to the system configuration described herein.

For example, the method for depositing a thin film on a substrate can include heating a first source material in a first receptacle positioned within a first chamber of a deposition head to form first source vapors, and directing the first source vapors through a distribution plate. A second source material can also be heated in a second receptacle positioned within a second chamber of the deposition head to form second source vapors, which can then be directed through the distribution plate. A substrate can be transported past the distribution plate such that a first majority of the first source vapors deposit on a deposition surface of the substrate prior to a second majority of the second source vapors.

In one particular embodiment of the method, the first source material can include cadmium telluride, and the second source material can include telluride. For example, the second source material can include telluride with a reduced stoichiometric amount (than CdTe), or substantially free from, cadmium. In one embodiment, the second source material can consist essentially of (e.g., consist of) telluride. As such, the second source material depositing onto the CdTe layer (formed from the deposited first source material) can be telluride-rich.

Alternatively, in one embodiment of the method, the first source material can include cadmium telluride, and the second source material can include cadmium chloride. As such, the second source material depositing onto the CdTe layer (formed from the deposited first source material) can treat the CdTe layer with cadmium chloride.

Desirably, the process embodiments include continuously conveying the substrates at a constant linear speed during the vapor deposition process.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

1. An apparatus for vapor deposition of a sublimated source material as a thin film on discrete photovoltaic module substrates conveyed in a continuous non-stop manner through said apparatus, the apparatus comprising:
a deposition head comprising a first sublimation compartment and a second sublimation compartment, wherein the first sublimation compartment is configured for receipt and sublimation of a first source material and the second sublimation compartment is configured for receipt and sublimation of a second source material;
a first distribution plate at a defined distance above a horizontal conveyance plane of an upper surface of substrates conveyed through a first deposition area of said apparatus, wherein said first distribution plate is positioned between the first sublimation compartment and the horizontal conveyance plane; and,
a second distribution plate at a defined distance above a horizontal conveyance plane of an upper surface of substrates conveyed through a second deposition area of said apparatus, wherein said second distribution plate is positioned between the second sublimation compartment and the horizontal conveyance plane.

2. The apparatus of claim 1, wherein the first sublimation compartment and the second sublimation compartment are isolated from each other such that the sublimated first source material is substantially prevented from mixing with the sublimated second source material.

3. The apparatus of claim 1, wherein the first sublimation compartment comprises a first receptacle configured for receipt of the first source material and a first heated distribution manifold disposed below said first receptacle, said first heated distribution manifold configured to heat said first receptacle to a degree sufficient to sublimate the first source material within said first receptacle.

4. The apparatus of claim 3, wherein said first heated distribution manifold defines a plurality of first passages to allow passage of sublimated first source material therethrough, and first internal heating elements arranged between said first passages in said first heated distribution manifold.

5. The apparatus as in claim 4, further comprising a first movable shutter plate disposed above said first distribution manifold, said first shutter plate comprising a plurality of first passages therethrough that align with said first passages in said first distribution manifold in an on-position of said first shutter plate to allow passage of sublimated first source material through said first heated distribution manifold, said first shutter plate movable to an off-position wherein said first shutter plate blocks said first passages in said first heated distribution manifold to flow of sublimated first source material therethrough.

6. The apparatus as in claim 5, wherein said first distribution manifold comprises a first upper shell member and a first lower shell member, said first shell members defining internal cavities in which said first heating elements are disposed.

7. The apparatus of claim 3, wherein the second sublimation compartment comprises a second receptacle configured for receipt of the second source material and a second heated distribution manifold disposed below said second receptacle, said second heated distribution manifold configured to heat said second receptacle to a degree sufficient to sublimate the second source material within said second receptacle.

8. The apparatus of claim 7, wherein said second heated distribution manifold defines a plurality of second passages to allow passage of sublimated second source material therethrough, and second internal heating elements arranged between said second passages in said second heated distribution manifold.

9. The apparatus as in claim 8, further comprising a second movable shutter plate disposed above said second distribution manifold, said second shutter plate comprising a plurality of second passages therethrough that align with said second passages in said second distribution manifold in an on-position of said second shutter plate to allow passage of sublimated second source material through said second heated distribution manifold, said second shutter plate movable to an off-position wherein said second shutter plate blocks said second passages in said second heated distribution manifold to flow of sublimated second source material therethrough.

10. The apparatus as in claim 9, wherein the first shutter plate and the second shutter plate are independently controllable.

11. The apparatus as in claim 9, wherein said second distribution manifold comprises a second upper shell member and a second lower shell member, said second shell members defining internal cavities in which said second heating elements are disposed.

12. The apparatus of claim 7, further comprising:
a first controller configured to control the temperature of the first heated distribution manifold; and
a second controller configured to control the temperature of the second heated distribution manifold,
wherein the first controller and the second controller are independent from one another.

13. The apparatus of claim 1, further comprising:
a seal member positioned between the first distribution plate and a second distribution plate such that source vapors are substantially prevented from mixing between the first deposition area and the second deposition area.

14. The apparatus of claim 1, further comprising:
a seal member positioned between the first distribution plate and a second distribution plate, wherein the seal member is disposed at a gap distance above the horizontal conveyance plane that is less than the distance between the horizontal conveyance plane and said first distribution plate and having a ratio of longitudinal length to gap distance of from about 10:1 to about 100:1.

15. The apparatus of claim 1, wherein the first deposition area and the second deposition area define a single continuous deposition area.

16. The apparatus of claim 1, further comprising:
a conveyor disposed below said deposition head, said conveyor comprising a plurality of interconnected slats, each of said slats having a respective flat planar outer surface and transverse edge profiles such that said outer surfaces of said slats lie in a common horizontal plane and define an uninterrupted flat support surface for the substrates conveyed through said apparatus.

17-19. (canceled)

20. An apparatus for depositing a thin film on a substrate, comprising:
a deposition head that defines a first chamber and a second chamber;
a first receptacle positioned within the first chamber, wherein the first receptacle is configured to hold a first source material;
a first heated distribution manifold configured to heat the first source material to create first source vapors;
a second receptacle positioned within the second chamber, wherein the second receptacle is configured to hold a second source material;
a second heated distribution manifold configured to heat the second source material to create second source vapors;
a distribution plate defining holes therethrough, wherein the distribution plate is positioned between the first receptacle and a deposition surface of a substrate and between the second receptacle and the deposition surface of the substrate such that the first source vapors and the second source vapors pass through the distribution plate; and,
a conveyor system configured to transport the substrate past the deposition head such that a first majority of the first source vapors deposit on the deposition surface of the substrate prior to a second majority of the second source vapors.
